(19) United States
(12) Patent Application Publication
(10) Pub. No.: US 2024/0389438 A1
(43) Pub. Date: Nov. 21, 2024

(54) WINDOW AND DISPLAY DEVICE INCLUDING THE SAME

(71) Applicant: SAMSUNG DISPLAY CO., LTD., YONGIN-SI (KR)

(72) Inventors: JUYOUNG YOON, Yongin-si (KR); JAEWOO IM, Yongin-si (KR); MYUNG-SEOK KWON, Yongin-si (KR); DAHYE KIM, Yongin-si (KR); SANGWON LEE, Yongin-si (KR)

(21) Appl. No.: 18/666,575

(22) Filed: May 16, 2024

(30) Foreign Application Priority Data
May 19, 2023 (KR) 10-2023-0065066

(51) Int. Cl. H10K 59/80; G02B 1/11; G02B 1/18

(52) U.S. Cl. CPC H10K 59/879; G02B 1/11; G02B 1/18

(57) ABSTRACT

A window includes a base layer, a first layer having a first refractive index, a second layer having a second refractive index, and a third layer having a third refractive index. In the window, the first refractive index is within a range of about 1.7 to about 1.9, and when the first refractive index is within a range of about 1.7 to about 1.8, the second refractive index is within a range of about 2.0 to about 2.4, and when the first refractive index is greater than about 1.8 and at most about 1.9, the second refractive index is in a range satisfied by the expression: 2.0≤n2≤(−3×n1)+7.8 where, n1 is the first refractive index, and n2 is the second refractive index.

### CROSS-REFERENCE TO RELATED APPLICATIONS

This U.S. non-provisional patent application claims priority under 35 U.S.C. § 119 to Korean Patent Application No. 10-2023-0065066, filed on May 19, 2023, the entire contents of which are hereby incorporated by reference.

### TECHNICAL FIELD

The present disclosure relates to a display device, and more particularly, to a display device window and a display device including the window.

### DISCUSSION OF THE RELATED ART

To provide image information to a user, display devices are used in various multimedia apparatuses, such as televisions, mobile phones, tablet computers, and portable game consoles. In recent days, various types of flexible display devices capable of folding or bending to a noticeable degree without cracking or otherwise sustaining damage have been developed. Flexible display devices may be transformed, for example, folded, rolled, or bent, into various shapes, thereby making them easy to carry.

A display device may include a display panel for displaying an image, and a window. The window is disposed on a front surface of the display device, and thus protects the display panel from an external impact. The window may be deformed by a folding or bending operation or easily damaged by an external impact. Accordingly, a window capable of exhibiting excellent strength and high display quality, may be used.

### SUMMARY

A window includes a base layer, a first layer disposed on the base layer, and having a first refractive index within a range of about 1.7 to about 1.9, a second layer disposed on the first layer, and having a second refractive index that is larger than the first refractive index, and a third layer disposed on the second layer, and having a third refractive index that is less than each of the first refractive index and the second refractive index. When the first refractive index is within a range of about 1.7 to about 1.8, the second refractive index is in a range of about 2.0 to about 2.4, and when the first refractive index is greater than about 1.8 and equal to or less than about 1.9, the second refractive index is in a range of:

$$2. \leq n 2 \leq ( - 3 \times n 1 ) + 7.8$$

where, n1 is the first refractive index, and n2 is the second refractive index.

The window may further include an anti-fingerprint layer disposed on the third layer.

The second layer may be directly disposed on the first layer, the third layer may be disposed directly on the second layer, and the anti-fingerprint layer may be disposed directly on the third layer.

The window may further include an adhesive layer disposed between the first layer and the second layer, and/or between the second layer and the third layer.

The first layer may have a thickness within a range of about 50 nm to about 95 nm, the second layer may have a thickness within a range of about 50 nm to about 150 nm, the third layer may have a thickness within a range of about 50 nm to about 80 nm, and the anti-fingerprint layer may have a thickness within a range of about 20 nm to about 45 nm.

First to fourth reflectances on an upper surface of the anti-fingerprint layer may be each about 1% or less, the second reflectance may be higher than the third reflectance, the first reflectance may be an SC reflectance in a wavelength range of about 445 nm to about 455 nm, the second reflectance may be an SC reflectance in a wavelength range of about 520 nm to about 530 nm, the third reflectance may be an SC reflectance in a wavelength range of about 550 nm to about 560 nm, and the fourth reflectance may be an SC reflectance in a wavelength range of about 620 nm to about 630 nm.

The second reflectance may be at least equal to the first reflectance, the fourth reflectance may be greater than the third reflectance, and a difference between the second reflectance and the third reflectance may be at least 0.1.

The window may include a first point in which the first refractive index is about 1.7, and the second refractive index is about 2.0; a second point in which the first refractive index is about 1.9, and the second refractive index is about 2.0; a third point in which the first refractive index is about 1.9, and the second refractive index is about 2.1; a fourth point in which the first refractive index is about 1.8, and the second refractive index is about 2.4; and a fifth point in which the first refractive index is about 1.7, and the second refractive index is about 2.4. In this case, within an area of a polygon, which is formed by connecting the first to fifth points, the first reflectance may be about 0.01% to about 0.8%, the second reflectance may be about 0.15% to about 0.8%, the third reflectance may be about 0.04% to about 0.3%, and the fourth reflectance may be about 0.15% to about 0.7%.

The third layer may have a refractive index within a range of about 1.48 to about 1.50.

The third layer may include silicon dioxide (SiO₂).

A ratio of the first refractive index to the second refractive index may be about 1:1.1 to about 1:1.4.

The first layer may include tantalum pentoxide (Ta₂O₅) and aluminum oxide (Al₂O₃).

The second layer may include tantalum pentoxide (Ta₂O₅) and zirconium oxide (ZrO₂).

A luminous reflectance on an uppermost surface may be about 0.5% or less.

A saturation of C* may be 3 or less.

A window includes a base layer; a first layer disposed on the base layer, and having a first refractive index within a range of about 1.7 to about 1.9; a second layer disposed on the first layer, and having a second refractive index that is higher than the first refractive index; and a third layer disposed on the second layer, and having a third refractive index that is lower than the first refractive index. On an uppermost surface, the window has first to fourth reflectances, each of which is about 1% or less, the first reflectance is about 0.01% to about 0.8% in a wavelength range of about 445 nm to about 455 nm, the second reflectance is about 0.15% to about 0.8% in a wavelength range of about 520 nm to about 530 nm, the third reflectance is about 0.04% to about 0.3% in a wavelength range of about 550 nm to about 560 nm, and the fourth reflectance is about 0.15% to about 0.7% in a wavelength range of about 620 nm to about 630 nm.

A display device includes a display module including a base substrate, a circuit layer disposed on the base substrate, a light-emitting element layer disposed on the circuit layer, a sensor layer disposed on the light-emitting element layer, and a light control layer disposed on the sensor layer. A window is disposed on the display module. The display device may include the above-described window.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a combined perspective view of a display device according to an embodiment of the inventive concept;

FIG. 1B is an exploded perspective view of a display device according to an embodiment of the inventive concept;

FIG. 2 is a cross-sectional view of a display device according to an embodiment of the inventive concept;

FIG. 3 is a cross-sectional view illustrating a part of a display module according to an embodiment of the inventive concept;

FIGS. 4A and 4B are each a cross-sectional view of a window according to an embodiment of the inventive concept;

FIG. 5A is a graph showing refractive indexes of a first layer and a second layer included in a window according to an embodiment of the inventive concept; and

FIG. 5B is a graph showing reflectances at some points illustrated in FIG. 5A.

### DETAILED DESCRIPTION

In this specification, it will be understood that when an element (or a region, a layer, a portion, or the like) is referred to as “being on”, “connected to” or “coupled to” another element, it may be directly disposed on, connected or coupled to the other element, or intervening elements may also be disposed therebetween.

In describing drawings, like reference numerals may refer to like elements throughout the specification and the drawings. In addition, in the accompanying drawings, a thickness, a ratio, and a size of components may be exaggerated for effective descriptions of technical contents. The term “and/or” includes all combinations of one or more of which associated configurations may define.

The terms of first, second, and the like may be used herein to describe various elements, and the elements should not necessarily be limited by terms. The terms are used to distinguish one element from another element. For example, a first component may be referred to as a second component without departing from the scope of the inventive concept, and likewise a second component may be referred to as a first component. The singular terms include the plural terms as well unless the context clearly indicates otherwise.

Furthermore, terms, such as “lower” or “bottom” and “upper”, or “top” may be used herein to describe one element's relationship to another element as illustrated in the Figures. The terms have relative concepts, and will be described with respect to the directions shown in the drawings.

It is to be understood that the terms such as “including” or “having,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

Herein, when an element is referred to as being “directly disposed on,” other layers, membranes, regions, or plates, there are no intervening layers, membranes, regions, or plates present. For example, “directly disposed on” may mean that two layers or two members are directly disposed without using an additional intervening member, such as an adhesive member.

Hereinafter, embodiments of the inventive concept will be explained in detail with reference to the accompanying drawings.

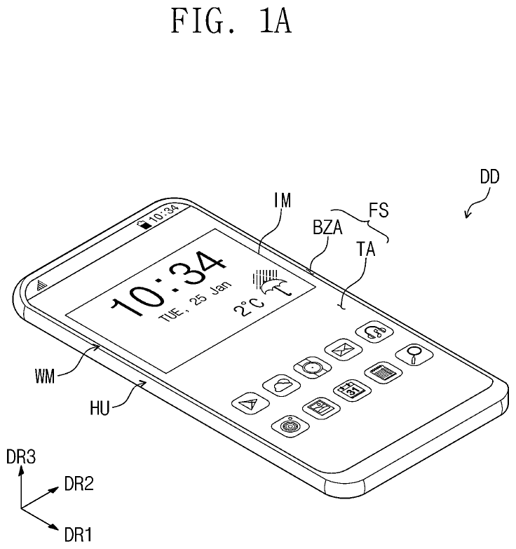

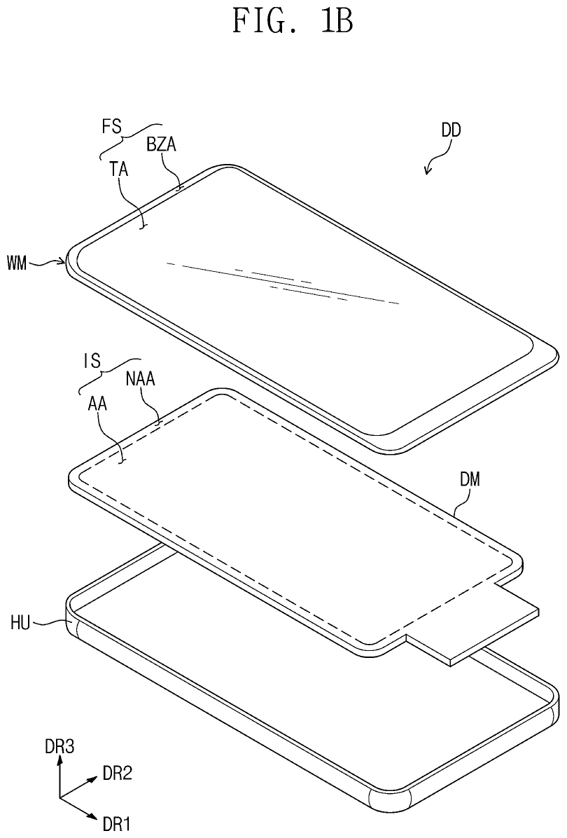

FIG. 1A is a combined perspective view of a display device according to an embodiment of the inventive concept. FIG. 1B is an exploded perspective view of a display device according to an embodiment of the inventive concept.

Referring to FIG. 1, a display device DD may be activated in response to an electrical signal. The display device DD may display an image IM and detect an external input, such as a touch of a user and/or a stylus pen. The display device DD may include various embodiments. For example, the display device DD may include a tablet computer, a laptop computer, a computer monitor, a smart television, etc. In the present embodiment, a smart phone is exemplarily illustrated as the display device DD.

The display device DD may display, in a third direction DR3, an image IM on a display surface FS, which is parallel to each of a first direction DR1 and a second direction DR2. A display surface FS, on which the image IM is displayed, may correspond to a front surface of the display device DD, and correspond to a front surface of a window WM. Hereinafter, the display surface and the front surface of the display device DD, and the front surface of the window WM will be denoted as the same reference symbol. The image IM may include not only a dynamic (i.e., moving) image but also a still image. FIG. 1A illustrates a clock and a plurality of icons as an example of the image IM.

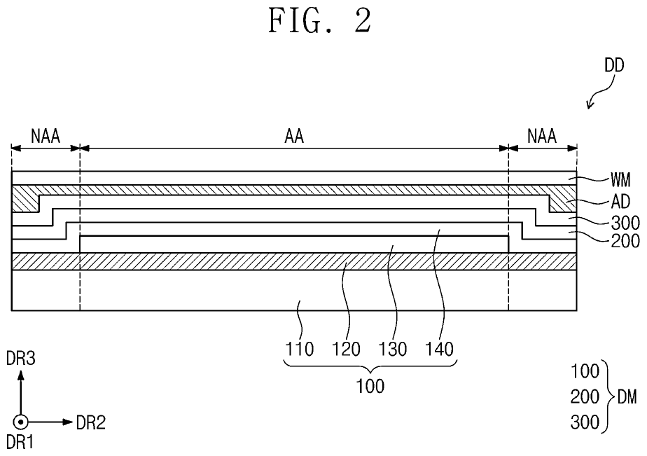

In an embodiment of the inventive concept, a front surface (or an upper surface) and a rear surface (or a bottom surface) of each member are defined with respect to a direction in which the image IM is displayed. The front surface and the rear surface may be opposed to each other in the third direction DR3, and a normal direction of each of the front surface and the rear surface may be parallel to the third direction DR3. A separation distance between the front surface and the rear surface in the third direction DR3 may correspond to a thickness of a display panel 100 (see FIG. 2) in the third direction DR3. Directions indicated by the first to third directions DR1, DR2, and DR3 are relative concepts and may thus be changed to other directions. In addition, as used herein, “on a plane” or “in a plan view” may mean when viewed from the third direction DR3.

The display device DD, according to an embodiment of the inventive concept, may detect a user's input. The user's input may include various types of external inputs such as a touch by a part of a user's body, light, heat, or pressure. The user's input may be provided in various types, and the display device DD may also detect a user's input applied to a side surface or rear surface of the display device DD according to the structure of the display device DD. However, an embodiment of the inventive concept is not necessarily limited thereto.

As illustrated in FIGS. 1A and 1B, the display device DD include a window WM, a display module DM, and an outer case HU. As used herein, the window WM and the outer case HU are coupled to form an exterior of the display device DD. As used herein, the outer case HU, the display module DM, and the window WM may be sequentially stacked along the third direction DR3.

The window WM may include an optically transparent material (e.g., substantially transparent to visible light). The window WM may include an insulating panel. For example, the window WM may be formed from glass, plastic, or a combination thereof.

The front surface FS of the window WM may define the front surface of the display device DD as described above. A transmissive region TA may be an optically transparent region. For example, the transmissive region TA may have visible light transmittance of at least about 90%.

A bezel region BZA may have a lower light transmittance than the transmissive region TA. The bezel region BZA may define a shape of the transmissive region TA. The bezel region BZA may be adjacent to the transmissive region TA and may at least partially surround the transmissive region TA.

The bezel region BZA may have a predetermined color. The bezel region BZA may cover a peripheral region NAA of the display module DM to block the peripheral region NAA from being viewed from the outside. This configuration is provided as an example, and in the window WM according to an embodiment of the inventive concept, the bezel region BZA may also be omitted.

The display module DM may display an image IM and detect an external input. The image IM may be displayed on a front surface IS of the display module DM. The front surface IS of the display module DM may include an active region AA and a peripheral region NAA. The active region AA may be activated in response to an electrical signal.

In this embodiment, the active region AA may be a region in which an image IM is displayed, and also a region in which an external input is detected. The transmissive region TA overlaps at least the active region AA. For example, the transmissive region TA may overlap a front surface or at least a portion of the active region AA. Accordingly, a user may view an image IM or provide an external input through the transmissive region TA. However, this is illustrated as an example, and in the active region AA, a region in which an image IM is displayed, and a region in which an external input is detected may also be separated from each other. However, an embodiment of the inventive concept is not necessarily limited thereto.

The peripheral region NAA may be covered by the bezel region BZA. The peripheral region NAA may be adjacent to the active region AA. The peripheral region NAA may at least partially surround the active region AA. In the peripheral region NAA, a driving circuit, a driving line, or the like, for driving the active region AA may be disposed.

The display module DM may include a display panel and a sensor layer. An image IM may be substantially displayed on the display panel, and an external input may be substantially detected on the sensor layer. The display module DM include both display panel and the sensor layer, thus making it possible to display an image IM and detect an external input simultaneously. A detailed description thereof will be described later.

The display device DD, according to an embodiment, may further include a driving circuit. The driving circuit may include a flexible printed circuit board and a main circuit board. The flexible printed circuit board may be electrically connected to the display module DM. The flexible printed circuit board may connect the display module DM with the main circuit board. However, this is illustrated as an example. The flexible printed circuit board, according to an embodiment of the inventive concept, might not be connected to the main circuit board, and the flexible printed circuit board may be a rigid substrate.

The flexible printed circuit board may be connected to pads of the display module DM, disposed in the peripheral region NAA. The flexible printed circuit board may provide an electrical signal for driving the display module DM, to the display module DM. The electrical signal may be generated from the flexible printed circuit board or generated from the main circuit board. The main circuit board may include various driving circuits for driving the display module DM or a connector for supplying power. The main circuit board may be connected to the display module DM via the flexible printed circuit board.

FIG. 1B exemplarily illustrates an unfolded state of the display module DM, but at least a portion of the display module DM may be bent. In the embodiment, a portion of the display module DM may be bent toward the rear surface of the display module DM, and the portion bent toward the rear surface may be a portion to which the main circuit board is connected. Accordingly, the main circuit board may be assembled while overlapping with the rear surface of the display module DM.

The outer case HU is coupled to the window WM to define the exterior of the display device DD. The outer case HU provides a predetermined inner space. The display module DM may be accommodated in the inner space of the outer case HU.

The outer case HU may include a material having relatively high stiffness. For example, the outer case HU may include a plurality of frames and/or a plate formed of glass, plastic, or metal, or a combination thereof. The outer case HU may reliably protect components of the display device DD, which are accommodated in the inner space, from an external impact.

Material stiffness may be the resistance of the material to deformation or change in shape when subjected to an external force. Stiffness may be measured by a modulus of elasticity, which may be known as a Young's modulus. A material may be considered to have a relatively high stiffness, for example, when its Young's modulus of 10 GPa or more.

FIG. 2 is a cross-sectional view of a display device according to an embodiment of the inventive concept. Referring to FIG. 2, the display device DD may include a display module DM and a window WM. The display module DM and the window WM may be coupled via an adhesive layer AD.

In the display device DD, according to an embodiment, the display module DM may include a display panel 100, and a sensor layer 200, and include an anti-reflective layer 300 as a light control layer. The anti-reflective layer 300 among a plurality of layers included in the display module DM may be connected to the window WM via the adhesive layer AD.

The display panel 100 may be a component that substantially generates an image. The display panel 100 may be a light-emitting type display panel, and for example, the display panel 100 may be an organic light-emitting diode (OLED) display panel, an inorganic light-emitting display panel, a micro-LED display panel, or a nano LED display panel. The display panel 100 may also be referred to as a display layer. The display panel 100 include a base substrate 110, a circuit layer 120, a light-emitting element layer 130, and an encapsulation layer 140.

The base substrate 110 may be a member that provides a base surface on which the circuit layer 120 is disposed. The base substrate 110 may be a rigid substrate, or a flexible substrate capable of bending, folding, rolling, etc. The base substrate 110 may be a glass substrate, a metal substrate, a polymer substrate, etc. However, an embodiment of the inventive concept is not necessarily limited thereto, and the base substrate 110 may be an inorganic layer, an organic layer, or a composite material layer.

The base substrate 110 may have a multilayer structure (e.g., including two or more layers). For example, the base substrate 110 may include a first synthetic resin layer, an inorganic layer having a multilayer or a single layer, and a second synthetic resin layer disposed on the inorganic layer having a multilayer or a single layer. The first and second synthetic resin layers may each include a polyimide-based resin but is not necessarily particularly limited thereto.

The circuit layer 120 may be disposed on the base substrate 110. The circuit layer 120 may include an insulating layer, a semiconductor pattern, a conductive pattern, and a signal line, etc.

The light-emitting element layer 130 may be disposed on the circuit layer 120. The light-emitting element layer 130 may include a light-emitting element. For example, the light-emitting element include an organic light-emitting material, an inorganic light-emitting material, an organic-inorganic light-emitting material, a quantum dot, a quantum rod, a micro-LED, or a nano LED.

The encapsulation layer 140 may be disposed on the light-emitting element layer 130. The encapsulation layer 140 may protect the light-emitting element layer 130 from foreign substances such as moisture, oxygen, and dust particles. The encapsulation layer 140 may include at least one inorganic layer. The encapsulation layer 140 may include a stacked structure of inorganic layer/organic layer/inorganic layer.

The sensor layer 200 may be disposed on the display panel 100. The sensor layer 200 may detect an external input. The external input may be a user's input. The user's input may include various types of external inputs such as a touch by a part of a user's body, light, heat, a stylus/pen, or pressure.

The sensor layer 200 may be formed on the display panel 100 through a continuous process. In this case, the sensor layer 200 may be directly disposed on the display panel 100. Herein, the wording, “directly disposed” may indicate that no third component is disposed between the sensor layer 200 and the display panel 100. For example, no additional adhesive member may be disposed between the sensor layer 200 and the display panel 100.

A light control layer may be disposed on the sensor layer 200. For example, the anti-reflective layer 300 may be directly disposed on the sensor layer 200. The anti-reflective layer 300 may reduce a reflectance with respect to external light incident from the outside of the display device DD. The anti-reflective layer 300 may be formed on the sensor layer 200 through a continuous process. The anti-reflective layer 300 may include color filters. The color filters may have a predetermined arrangement. For example, the color filters may be arranged in consideration of emission colors of pixels included in the display panel 100. In addition, the anti-reflective layer 300 may further include a black matrix adjacent to the color filters. A specific description of the anti-reflective layer 300 will be described later.

In an embodiment of the inventive concept, the sensor layer 200 may also be omitted. In this case, the anti-reflective layer 300 may be directly disposed on the display panel 100. In an embodiment of the inventive concept, the positions of the sensor layer 200 and the anti-reflective layer 300 may be interchanged.

In an embodiment of the inventive concept, the display device DD may further include an optical layer disposed on the anti-reflective layer 300. For example, the optical layer may be formed on the anti-reflective layer 300 through a continuous process. The optical layer may control a direction of light incident from the display panel 100, thereby increasing a front luminance of the display device DD. For example, the optical layer may include an organic insulating layer in which openings are respectively defined corresponding to light emitting regions of pixels included in the display panel 100, and a high-refractive-index layer covering the organic insulating layer and filling the openings. The high-refractive-index layer may have a higher refractive index than the organic insulating layer.

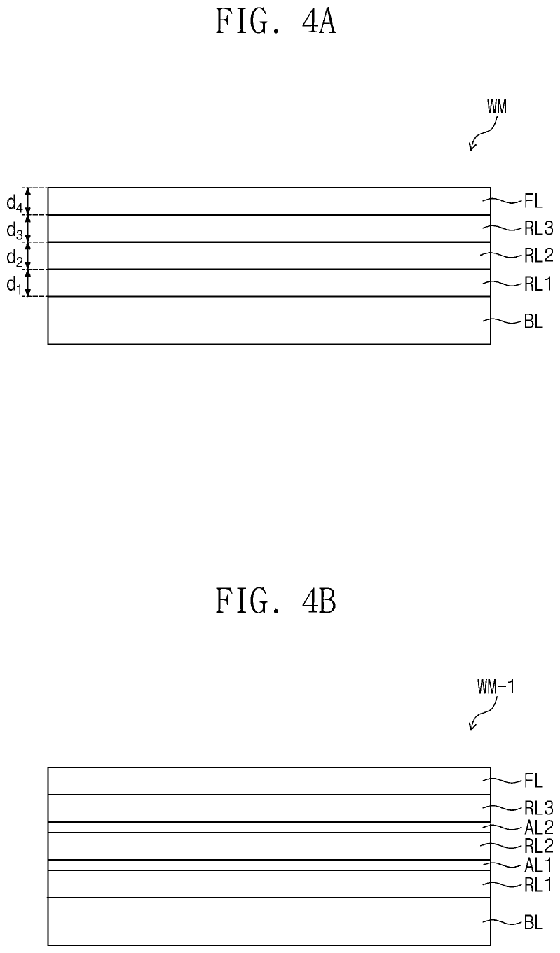

The window WM may provide a front surface of the display device DD. The window WM may be disposed on an upper side of the display module DM, and may cover the entire upper surface of the display module DM. The window WM may have a shape corresponding to a shape of the display module DM. The window WM may be a substrate or a film, which includes glass or a polymer material. In addition, the window WM may further include functional layers, such as a protective film, disposed on or above the substrate or film, which serves as a base. The functional layers included in the window WM will be described in more detail with reference to FIGS. 4A and 4B. The window WM may further include a bezel pattern overlapping the above-described bezel region BZA (see FIG. 1B).

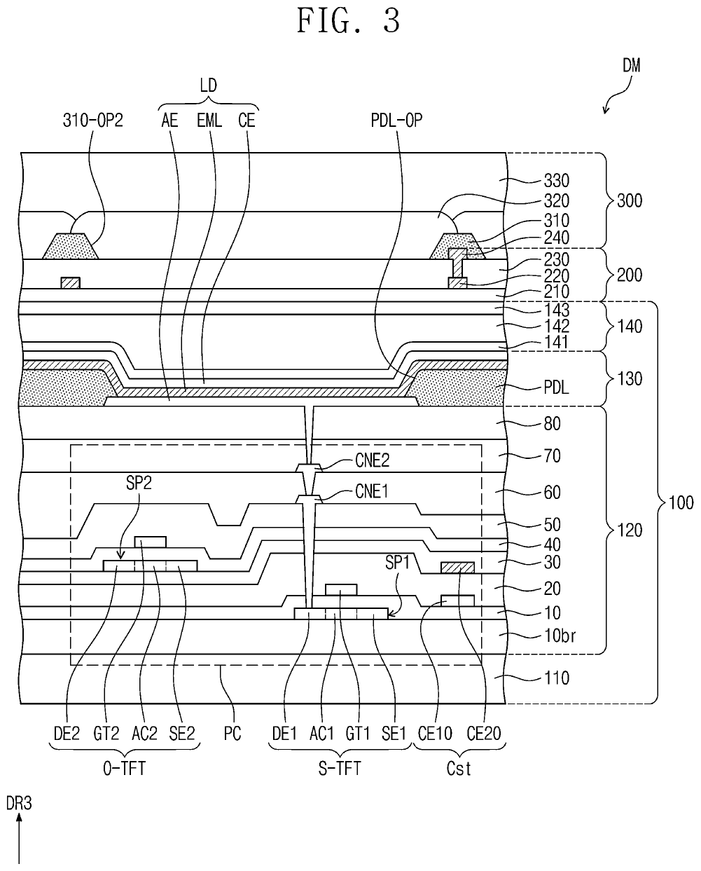

FIG. 3 is a cross-sectional view illustrating a portion of a display module according to an embodiment of the inventive concept. FIG. 3 is a partial cross-section illustrating one light-emitting element LD and a pixel circuit PC included in the display module DM.

The display panel 100 included in the display module DM, according to an embodiment, may include a base substrate 110. The base substrate 110 may be a member that provides a base surface on which the circuit layer 120 is disposed. The base substrate 110 may be a glass substrate, a metal substrate, a plastic substrate, a silicon substrate, etc. However, an embodiment of the inventive concept is not necessarily limited thereto, and the base substrate 110 may be an inorganic layer, an organic layer, or a composite material layer.

A buffer layer 10br may be disposed on the base substrate 110. The buffer layer 10br may prevent metal atoms or impurities from diffusing from the base substrate 110 to a first semiconductor pattern SP1 disposed thereabove. The first semiconductor pattern SP1 includes a channel region AC1 of a silicon transistor S-TFT. The buffer layer 10br controls a heat supply rate during a crystallization process for forming the first semiconductor pattern SP1, and thus the first semiconductor pattern SP1 may be uniformly formed.

The first semiconductor pattern SP1 may be disposed on the buffer layer 10br. The first semiconductor pattern SP1 may include a silicon semiconductor. For example, the silicon semiconductor may include amorphous silicon, polycrystalline silicon, or monocrystalline silicon, etc. For example, the first semiconductor pattern SP1 may include low-temperature polysilicon.

FIG. 3 illustrates a portion of the first semiconductor pattern SP1 disposed on the buffer layer 10br, and the first semiconductor pattern SP1 may further be disposed in another region. The first semiconductor pattern SP1 may be arranged over the pixels according to the specific rule. The first semiconductor pattern SP1 may have different electrical properties depending on whether or not it is doped. The first semiconductor pattern SP1 may include a first region having a relatively high conductivity and a second region having a relatively low conductivity. The first region may be doped with a N-type dopant, or a P-type dopant. A P-type transistor may include a doped region doped with a P-type dopant, and a N-type transistor may include a doped region doped with an N-type dopant. The second region may be an undoped region, or a doped region with a lower doping concentration than the first region.

Conductivity, as used herein, is electrical conductivity and measures how easily a material can conduct electricity. It is typically measured in units of siemens per meter (S/m) or ohms per meter (22/m). The higher the conductivity of a material, the easier it is for electricity to flow through it. A material with a conductivity of 1×10\hat{ }7 S/m or more may be considered high while a material with a conductivity of 1×10\hat{ }4 s/m or less may be considered low.

The conductivity of the first region is greater than the conductivity of the second region, and the first region may substantially serve as an electrode or a signal line. The second region may substantially correspond to an active region (or a channel) of a transistor. For example, a portion of the first semiconductor pattern SP1 may be an active region of a transistor, another portion may be a source or a drain of a transistor, and yet another portion may be a connection electrode or a connection signal line.

A source region SE1 (or a source), a channel region AC1 (or a channel) and a drain region DE1 (or a drain) of a silicon transistor S-TFT may be formed from the first semiconductor pattern SP1. The source region SE1 and the drain region DE1 may extend in opposite directions from the channel region AC1 on a cross section.

A back metal layer may be disposed under each of a silicon transistor S-TFT and an oxide transistor O-TFT. The back metal layer may be disposed overlapping the pixel circuit PC, and block external light from reaching the pixel circuit PC. The back metal layer may be disposed between the base substrate 110 and the buffer layer 10br. Alternatively, the back metal layer may be disposed between a second insulating layer 20 and a third insulating layer 30. The back metal layer may include a reflective or highly reflective metal. For example, the back metal layer may include silver (Ag), an alloy including silver (Ag), molybdenum (Mo), an alloy including molybdenum, aluminum (Al), an alloy including aluminum, aluminum nitride (AlN), tungsten (W), tungsten nitride (WN), copper (Cu), and p+ doped amorphous silicon, etc. Reflectiveness may be measured by a dimensionless number where 0 is no reflection and 1 is total reflection. Any material having a reflectiveness of 0.5 or more may be considered reflective, with a material having a reflectiveness of 0.9 or more being considered highly reflective. The back metal layer may be connected to an electrode or a wire and receive a constant voltage or a signal therefrom. According to an embodiment of the inventive concept, the back metal layer may also be a floating electrode, which is isolated from another electrode or wire. In an embodiment of the inventive concept, an inorganic barrier layer may be further disposed between the base substrate 110 and the buffer layer 10br.

A first insulating layer 10 may be disposed on the buffer layer 10br. The first insulating layer 10 may overlap a plurality of pixels in common and cover the first semiconductor pattern SP1. The first insulating layer 10 may be an inorganic layer and/or an organic layer and have a single- or a multi-layer structure. The first insulating layer 10 may include aluminum oxide, titanium oxide, silicon oxide, silicon nitride, silicon oxynitride, zirconium oxide, and/or hafnium oxide. In this embodiment, the first insulating layer 10 may be a single-layered silicon oxide layer. An insulating layer of the circuit layer 120 to be described later as well as the first insulating layer 10 may be an inorganic layer and/or an organic layer, and have a single- or a multi-layer structure. The inorganic layer may include at least one of the above-described materials, but is not necessarily limited thereto.

A gate GT1 of the silicon transistor S-TFT is disposed on the first insulating layer 10. The gate GT1 may be a portion of a metal pattern. The gate GT1 overlaps the channel region AC1. In a doping process of the first semiconductor pattern SP1, the gate GT1 may function as a mask. The gate GT1 may include titanium (Ti), silver (Ag), an alloy including silver, molybdenum (Mo), an alloy including molybdenum, aluminum (Al), an alloy including aluminum, aluminum nitride (AlN), tungsten, (W), tungsten nitride (WN), copper (Cu), indium tin oxide (ITO), indium zinc oxide (IZO), etc. However, an embodiment of the inventive concept is not necessarily limited thereto.

A second insulating layer 20 may be disposed on the first insulating layer 10 and cover the gate GT1. A third insulating layer 30 may be disposed on the second insulating layer 20. A second electrode CE20 of a storage capacitor Cst may be disposed between the second insulating layer 20 and the third insulating layer 30. In addition, a first electrode CE10 of the storage capacitor Cst may be disposed between the first insulating layer 10 and the second insulating layer 20.

A second semiconductor pattern SP2 may be disposed on the third insulating layer 30. The second semiconductor pattern SP2 may include a channel region AC2 of an oxide transistor O-TFT, which will be described later. The second semiconductor pattern SP2 may include an oxide semiconductor. The second semiconductor pattern SP2 may include a transparent conductive oxide (TCO) such as indium tin oxide (ITO), indium zinc oxide (IZO), indium gallium zinc oxide (IGZO), zinc oxide (ZnO) or indium oxide (In₂O₃).

The oxide semiconductor may include a plurality of regions, which are classified depending on whether or not the transparent conductive oxide is reduced. A region (hereinafter, referred to as a reduced region) in which the transparent conductive oxide is reduced, has higher conductivity than a region (hereinafter, referred to as a non-reduced region) in which no transparent conductive oxide is reduced. The reduced region substantially serves as a source/drain of a transistor or signal line. The non-reduced region substantially corresponds to a semiconductor region (or an active region or channel) of a transistor. For example, a partial region of the second semiconductor pattern SP2 may be a semiconductor region of the transistor, another partial region may be a source/drain region of the transistor, and yet another partial region may be a signal transmission region.

A source region SE2 (or a source), a channel region AC2 (or a channel) and a drain region DE2 (or a drain) of an oxide transistor O-TFT may be formed from the second semiconductor pattern SP2. The source region SE2 and the drain region DE2 may extend in opposite directions from the channel region AC2 in a cross-sectional view.

A fourth insulating layer 40 may be disposed on the third insulating layer 30. The fourth insulating layer 40 may overlap a plurality of pixels in common and cover the second semiconductor pattern SP2. The fourth insulating layer 40 may also be provided in a form of an insulating pattern, which overlaps a gate GT2 of the oxide transistor O-TFT, and exposes the source region SE2 and the drain region DE2 of the oxide transistor O-TFT.

The gate GT2 of the oxide transistor O-TFT is disposed on the fourth insulating layer 40. The gate GT2 of the oxide transistor O-TFT may be a portion of a metal pattern. The gate GT2 of the oxide transistor O-TFT overlaps the channel region AC2.

A fifth insulating layer 50 may be disposed on the fourth insulating layer 40 and cover the gate GT2. A first connection electrode CNE1 may be disposed on the fifth insulating layer 50. The first connection electrode CNE1 may be connected to the drain region DE1 of the silicon transistor S-TFT through a contact hole, which penetrates the first to fifth insulating layers 10, 20, 30, 40, and 50.

A sixth insulating layer 60 may be disposed on the fifth insulating layer 50. A second connection electrode CNE2 may be disposed on the sixth insulating layer 60. The second connection electrode CNE2 may be connected to the first connection electrode CNE1 through a contact hole, which penetrates the sixth insulating layer 60. A seventh insulating layer 70 may be disposed on the sixth insulating layer 60 and may cover the second connection electrode CNE2. An eighth insulating layer 80 may be disposed on the seventh insulating layer 70.

The sixth insulating layer 60, the seventh insulating layer 70, and the eighth insulating layer 80 may each be an organic layer. For example, the sixth insulating layer 60, the seventh insulating layer 70, and the eighth insulating layer 80 may each include a general purpose polymer such as benzocyclobutene (BCB), polyimide, hexamethyldisiloxane (HMDSO), polymethylmethacrylate (PMMA), polystyrene (PS), a polymer derivative having a phenol-based group, an acryl-based polymer, an imide-based polymer, and an aryl ether-based polymer, an amide-based polymer, a fluorine-based polymer, a p-xylene-based polymer, a vinyl alcohol-based polymer, a blend thereof, etc.

A light-emitting element LD may include a first electrode AE (or a pixel electrode), a light-emitting layer EML, and a second electrode CE (or a common electrode). The light-emitting layer EML and the second electrode CE may each be formed in a plurality of pixels in common.

The first electrode AE of the light-emitting element LD may be disposed on the eighth insulating layer 80. The first electrode AE of the light-emitting element LD may be a transmissive electrode, a semi-transmissive electrode, or a reflective electrode. According to an embodiment of the inventive concept, the first electrode AE of the light-emitting element LD may include a reflective layer formed of Ag, Mg, Al, Pt, Pd, Au, Ni, Nd, Ir, Cr, or a compound thereof, and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For example, the first electrode AE of the light-emitting element LD may include a stacked structure of ITO/Ag/ITO.

A pixel definition film PDL may be disposed on the eighth insulating layer 80. The pixel definition film PDL may have light-absorbing properties, and for example, the pixel definition film PDL may have a black color. The pixel definition film PDL may include a black coloring agent. The black coloring agent may include a black dye or a black pigment. The black coloring agent may include carbon black, a metal such as chromium, or an oxide thereof. The pixel definition film PDL may correspond to a light-blocking pattern having light-blocking properties.

The pixel definition film PDL may cover a portion of the first electrode AE of the light-emitting element LD. For example, an opening PDL-OP exposing a portion of the first electrode AE of the light-emitting element LD may be defined in the pixel definition film PDL. The pixel definition film PDL may increase a distance between an edge of the first electrode AE and the second electrode CE of the light-emitting element LD. Therefore, the pixel definition film PDL may serve to prevent an arc or the like from occurring at an edge of the first electrode AE.

A hole control layer may be disposed between the first electrode AE and the light-emitting layer EML. The hole control layer may include a hole transport layer, and further include a hole injection layer and/or an electron blocking layer. An electron control layer may be disposed between the light-emitting layer EML and the second electrode CE. The electron control layer may include an electron transport layer, and further include an electron injection layer and/or a hole blocking layer. The hole control layer and the electron control layer may be formed in a plurality of pixels in common by using an open mask.

The encapsulation layer 140 may be disposed on the light-emitting element layer 130. The encapsulation layer 140 may include an inorganic layer 141, an organic layer 142, and an inorganic layer 143, which are sequentially stacked, but layers forming the encapsulation layer 140 are not necessarily limited thereto.

The inorganic layers 141 and 143 may protect the light-emitting element layer 130 from moisture and oxygen, and the organic layer 142 may protect the light-emitting element layer 130 from foreign substances such as dust particles. The inorganic layers 141 and 143 may include a silicon nitride layer, a silicon oxynitride layer, a silicon oxide layer, a titanium oxide layer, or an aluminum oxide layer, etc. The organic layer 142 may include an acryl-based organic layer, but is not necessarily limited thereto.

The sensor layer 200 may be disposed on the display panel 100. The sensor layer 200 may be referred to as a sensor, an input sensing layer, or an input sensing panel. The sensor layer 200 may include a sensor base layer 210, a first conductive layer 220, a sensing-insulating layer 230 and a second conductive layer 240.

The sensor base layer 210 may be directly disposed on the display panel 100. The sensor base layer 210 may be an inorganic layer including silicon nitride, silicon oxynitride, and/or silicon oxide. Alternatively, the sensor base layer 210 may also be an organic layer including an epoxy resin, an acrylic resin, or an imide-based resin. The sensor base layer 210 may have a single-layer structure, or may have a multilayer structure, in which layers are stacked along the third direction DR3.

The first conductive layer 220 and the second conductive layer 240 may each have a single-layer structure, or have a multilayer structure, in which layers are stacked along the third direction DR3. The first conductive layer 220 and the second conductive layer 240 may include conductive lines, which define a mesh-shaped sensing electrode. The conductive lines might not overlap the opening PDL-OP and overlap the pixel definition film PDL.

The conductive layer having a single-layer structure may include a metal layer or a transparent conductive layer. The metal layer may include, molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as PEDOT, a metal nanowire, graphene.

The conductive layer having a multilayer structure may include metal layers. The metal layers may include, for example, a three-layer structure of titanium/aluminum/titanium. The conductive layer having a multilayer structure may include at least one metal layer and at least one transparent conductive layer.

The sensing insulating layer 230 may be disposed between the first conductive layer 220 and the second conductive layer 240. The sensing insulating layer 230 may include an inorganic film. The inorganic film may include of aluminum oxide, titanium oxide, silicon oxide, silicon nitride, silicon oxynitride, zirconium oxide, and/or hafnium oxide.

Alternatively, the sensing insulating layer 230 may include an organic film. The organic film may include at least any one of acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The anti-reflective layer 300 may be disposed on the sensor layer 200. The anti-reflective layer 300 may include a light-blocking pattern 310, a plurality of color filters 320, and a planarization layer 330.

The anti-reflective layer 300 may lower an external light reflectance. The anti-reflective layer 300 may be a light control layer, which selectively transmit light. The anti-reflective layer 300 may include a plurality of color filters 320, and the plurality of color filters 320 may have a predetermined arrangement. The arrangement of the plurality of color filters 320 may be determined in consideration of emission colors of pixels included in the display panel 100. In the display module DM according to an embodiment, the anti-reflective layer 300 may include no phase retarder and no polarizer and may lower a reflectance of the display module DM through the plurality of color filters 320. In the display module DM according to an embodiment, the anti-reflective layer 300 might not include a polarizing film or polarizing layer. However, an embodiment of the inventive concept is not necessarily limited thereto, and the display module DM may also include a polarizing film or polarizing layer.

A material forming the light-blocking pattern 310 is not necessarily particularly limited as long as being a material that absorbs light. The light-blocking pattern 310 may be a layer having a black color, and the light-blocking pattern 310 according to an embodiment may include a black coloring agent. The black coloring agent may include a black dye or a black pigment. The black coloring agent may include carbon black, a metal such as chromium, or an oxide thereof.

The light-blocking pattern 310 may cover a second conductive layer 240 of the sensor layer 200. The light blocking pattern 310 may prevent external light reflection caused by the second conductive layer 240. The light-blocking pattern 310 may overlap a portion of the pixel definition film PDL.

A division opening 310-OP2 may be defined in the light-blocking pattern 310. The division opening 310-OP2 may overlap a first electrode AE of the light-emitting element LD. Any one of the pluralities of color filters 320 may overlap the first electrode AE of the light-emitting element LD. Any one of the pluralities of color filters 320 may cover the division opening 310-OP2. The plurality of color filters 320 may each be connected to the light-blocking pattern 310.

The planarization layer 330 may cover the light-blocking pattern 310 and the color filter 320. The planarization layer 330 may include an organic material and provide an upper surface thereof as a flat surface. In an embodiment of the inventive concept, the planarization layer 330 may also be omitted.

FIGS. 4A and 4B are each a cross-sectional view of a window according to an embodiment of the inventive concept. Windows WM and WM-1, according to embodiments of the inventive concept, may each include a base layer BL, a first layer RL1, a second layer RL2, a third layer RL3 and a fourth layer FL.

Referring to FIG. 4A, the window WM, according to an embodiment, may include a first layer RL1, a second layer RL2, a third layer RL3, and a fourth layer FL, which are sequentially stacked on the base layer BL. FIG. 4B, illustrates, compared to FIG. 4A, a cross-sectional view of the window WM-1, which further includes at least one of adhesive layers AL1 and AL2. The window WM-1 according to an embodiment, may include the adhesive layer AL1 between the first layer RL1 and the second layer RL2 and/or between the second layer RL2 and the third layer RL3. FIG. 4B exemplarily illustrates the window WM-1, in which the first adhesive layer AL1 is disposed between the first layer RL1 and the second layer RL2, and the second adhesive layer AL2 is disposed between the second layer RL2 and the third layer RL3. However, an embodiment of the inventive concept is not necessarily limited thereto, and the first adhesive layer AL1 and/or the second adhesive layer AL2 may be omitted. For example, any one of the first adhesive layer AL1 and the second adhesive layer AL2 may be omitted. Alternatively, as illustrated in FIG. 4A, both first adhesive layer AL1 and the second adhesive layer AL2 may be omitted.

The base layer BL may include a transparent material. In an embodiment, the base layer BL may include a glass, a tempered glass or a polymer film. In an embodiment, the base layer BL may be a glass substrate, which is chemically strengthened. For example, the base layer BL may be a chemically strengthened ultra-thin glass (UTG) substrate. When the base layer BL is a chemically strengthened glass substrate, the base layer BL may have increased mechanical strength while having a small thickness, and may thus be used as a window substrate of a foldable display device. When the base layer BL includes a polymer film, the base layer BL may include a polyimide (PI) film or a polyethylene terephthalate (PET) film. The base layer BL of each of the windows WM and WM-1 may have a multilayer structure or a single-layer structure. For example, the base layer BL may have a structure in which a plurality of polymer films is bonded via an adhesive member, or have a structure in which a glass substrate and a polymer film are bonded with an adhesive agent. The base layer BL may be formed of a flexible material.

The base layer BL may have a thickness within a range of about 20 μm to about 500 μm. When the base layer BL have a thickness within a range of less than about 20 μm, it may be difficult to serve as a support layer where the first layer RL1 and the like are provided, or to protect the display module DM (see FIG. 3) disposed thereunder. In addition, when the thickness of the base layer BL is greater than 500 μm, the total thickness of the display device DD (see FIG. 3) may increase. FIGS. 4A and 4B exemplarily illustrate that the base layer BL has a rectangular shape on a cross-section perpendicular to the thickness direction of the windows WM and WM-1. However, an embodiment of the inventive concept is not necessarily limited thereto, and an edge portion of an upper surface of the base layer BL may have a rounded shape due to a curved surface. For example, in the base layer BL, the edge portion of the upper surface which overlaps the bezel region BZA (see FIG. 1B), may have a rounded shape due to a curved surface.

The first layer RL1 has a higher refractive index than the base layer BL and may be a layer for lowering a reflectance of the surface of the windows WM and WM-1. The first layer RL1 may be disposed on the base layer BL. The first layer RL1 may be directly disposed on the base layer BL. The first layer RL1 may be disposed on the upper surface of the base layer BL, and a lower surface of the base layer BL may be adjacent to the above-described display module DM (see FIG. 2). For example, the first layer RL1 may be spaced apart from the display module DM with the base layer BL disposed therebetween.

The first layer RL1 may include a first material having a higher refractive index than the base layer BL and excellent adhesion to the base layer BL. In addition, the first material included in the first layer RL1 may have a lower refractive index than a material included in the second layer LR2. The first material may have a higher refractive index than a material included in the base layer BL and a lower refractive index than the material included in the second layer RL2. The first material included in the first layer RL1 may include tantalum pentoxide (Ta₂O₅) and/or aluminum oxide (Al₂O₃). For example, the first layer RL1 may include aluminum oxide (Al₂O₃) or include both tantalum pentoxide (Ta₂O₅) and aluminum oxide (Al₂O₃) as the first material. In an embodiment, the first layer RL1 may include a solid solution in which tantalum pentoxide and aluminum oxide are mixed.

The first layer RL1 may have a first thickness d₁. The first thickness d₁ may be, for example, within a range of about 40 nm to about 110 nm. When the first thickness d₁ is less than about 40 nm, the reflectance of the surface of the windows WM and WM-1 might not be sufficiently reduced. When the first thickness d₁ is greater than about 110 nm, the total thickness of the windows WM and WM-1 may increase, resulting in an excessive increase in the total thickness of the display device DD (see FIG. 2). The first thickness d₁ may be controlled within the above range to have a luminous reflectance of about 0.5% or less in the visible light wavelength region according to the refractive index of each of the first layer RL1 and the second layer RL2.

The first layer RL1 may be formed through an ion-assisted deposition process. The first layer RL1, as described above, may be formed of tantalum pentoxide and aluminum oxide. In the process of forming the first layer RL1, while tantalum pentoxide and aluminum oxide are each deposited on the surface of the base layer BL in particle form, an ionized argon (Ar) gas or an oxygen (O₂) gas is provided together during the deposition process, and thus, adhesion of a deposition film to the surface of the base layer BL may be increased.

The first layer RL1 may have a single-layer structure formed of a single material. The first layer RL1 may be a single layer formed of any one of tantalum pentoxide and aluminum oxide, or a single layer formed of a solid solution, in which tantalum pentoxide and aluminum oxide are mixed. For example, the first layer RL1 might not include a plurality of layers.

The second layer RL2 may be disposed on the first layer RL1. The second layer RL2 may have a higher refractive index than the base layer BL and the first layer RL1 and be a layer for lowering the reflectance of the surface of the windows WM and WM-1. The second layer RL2 may be directly disposed on the first layer RL1. However, an embodiment of the inventive concept is not necessarily limited thereto, and as illustrated in FIG. 4B, the first adhesive layer AL1 may also be disposed under the second layer RL2.

The first adhesive layer AL1 may be a layer for increasing adhesion between the first layer RL1 and the second layer RL2. The first adhesive layer AL1 may have excellent adhesion to each of the first layer RL1 and the second layer RL2, thereby increasing mutual adhesion between the first layer RL1 and the second layer RL2. The first adhesive layer AL1 may be disposed between the first layer RL1 and the second layer RL2.

The second layer RL2 may include a second material, which has a higher refractive index than that of the first layer RL1, and excellent adhesion to the first layer RL1. In addition, the second material included in the second layer RL2, may have a higher refractive index than the material included in the base layer BL. The second material may include tantalum pentoxide (Ta₂O₅) and/or zirconium oxide (ZrO₂). For example, the second layer RL2 may include, as the second material, tantalum pentoxide (Ta₂O₅) or include both tantalum pentoxide (Ta₂O₅) and zirconium oxide (ZrO₂). In an embodiment, the second layer RL2 may include a solid solution, in which tantalum pentoxide (Ta₂O₅) and zirconium oxide (ZrO₂) are mixed. The second layer RL2, in the same way as the first layer RL1, may be formed through the ion-assisted deposition process.

The second layer RL2 may have a second thickness d₂. The second thickness d₂ of the second layer RL2 may be, for example, about 50 nm to about 200 nm. When the second thickness d₂ is less than about 50 nm, the reflectance of the surface of the windows WM and WM-1 may be insufficiently reduced. When the second thickness d₂ is greater than about 200 nm, the total thickness of the windows WM and WM-1 may increase, resulting in an excessive increase in the total thickness of the display device DD. The second thickness d₂ may be controlled within the above range to have a luminous reflectance of about 0.5% or less in the visible light wavelength region according to the refractive index of each of the first layer RL1 and the second layer RL2.

The second layer RL2 may have a single-layer structure formed of a single material. The second layer RL2 may be a single layer formed of any one of tantalum pentoxide and zirconium oxide, or a single layer formed of a solid solution, in which tantalum pentoxide and zirconium oxide are mixed. For example, the second layer RL2 might not include a plurality of layers.

The third layer RL3 may be disposed on the second layer RL2. The third layer RL3 may increase adhesion between the second layer RL2 and a fourth layer FL. The third layer RL3 may be an adhesion promoter layer, which has excellent adhesion to each of the second layer RL2 and the fourth layer FL and thus increases mutual interlayer adhesion between the second layer RL2 and the fourth layer FL. The third layer RL3 may be directly disposed on the second layer RL2. However, an embodiment of the inventive concept is not necessarily limited thereto, and as illustrated in FIG. 4B, the second adhesive layer AL2 may also be disposed under the third layer RL3.

The second adhesive layer AL2 may increase adhesion between the second layer RL2 and the third layer RL3. The second adhesive layer AL2 may have excellent adhesion to each of the second layer RL2 and the third layer RL3, thereby making it possible to increase the mutual interlayer adhesion between the second layer RL2 and the third layer RL3. The second adhesive layer AL2 may be disposed between the second layer RL2 and the third layer RL3.

The third layer RL3 may include a material that has excellent mechanical strength and is for increasing adhesion while having similar refractive properties to those of the base layer BL. The third layer RL3 may include a third material, and the third material may include a material having a refractive index similar to the material included in the base layer BL. The third material included in the third layer RL3, may include, for example, silicon dioxide (SiO₂, or silica). In an embodiment, the third layer RL3 may include silicon dioxide (SiO₂) as a main component, and in addition to silicon dioxide (SiO₂), may further include alumina (Al₂O₃, or aluminum oxide), chromium oxide (Cr₂O₃), etc.

The third layer RL3 may have a third thickness d₃. The third thickness d₃ of the third layer RL3 may be, for example, about 50 nm to about 80 nm. When the third thickness d₃ is less than about 50 nm, an increasing of the adhesion between the second layer RL2 and the fourth layer FL might not be achieved, and mechanical strength of the windows WM and WM-1 may be reduced. When the third thickness d₃ is greater than about 80 nm, the reflectances of the windows WM and WM-1 may increase, and the total thickness of the window WM may increase, resulting in an excessive increase in the total thickness of the display device DD (see FIG. 2).

A refractive index of the third layer RL3 may be about 1.48 to about 1.50. The refractive index of the third layer RL3 may be a refractive index at a wavelength of about 550 nm. In the windows WM and WM-1, according to an embodiment, the refractive index of the third layer RL3 falls within the above-described range at a wavelength of about 550 nm, and thus reflectances of the surface of the windows WM and WM-1 may be reduced. The third layer RL3 may have lower refractive index compared to the first layer RL1 and the second layer RL2.

The third layer RL3 may have a single-layer structure formed of a single material. The third layer RL3 may be a single layer formed of silicon dioxide, or a single layer formed of silicon dioxide and a solid solution, in which silicon dioxide and aluminum oxide are mixed. For example, the third layer RL3 might not include a plurality of layers.

The fourth layer FL may be disposed on the third layer RL3 and may increase slip properties and scratch resistance of the surface of the windows WM and WM-1. In an embodiment, the fourth layer FL may be an anti-fingerprint layer that has excellent fingerprint resistance and suppresses a surface scratch. That is, hereinafter, the fourth layer FL may be referred to as an anti-fingerprint layer FL. The fourth layer FL may be directly disposed on the third layer RL3. The fourth layer FL may be disposed on an uppermost layer of the windows WM and WM-1, and an upper surface of the fourth layer FL may define an uppermost surface of the windows WM and WM-1.

The fourth layer FL may include a material that is excellent in scratch resistance and slip properties and has low-refractive-index properties. In an embodiment, the fourth layer FL may include a fluoride-including polymer. The fourth layer FL may include, for example, a perfluoropolyether (PFPE) compound. The fourth layer FL may include a perfluoropolyether silane, a perfluoroalkyl ether alkoxysilane, or a perfluoroalkyl ether copolymer, etc. The fourth layer FL includes the perfluoropolyether compound, and thus the fingerprint and scratch resistances of the fourth layer FL may be increased.

The fourth layer FL may have a fourth thickness d₄. The fourth layer FL may have the fourth thickness d₄, for example, about 20 nm to about 45 nm. When the fourth thickness d₄ is less than about 20 nm, the fingerprint and scratch resistances of the windows WM and WM-1 may be reduced. When the fourth thickness d₄ is greater than about 45 nm, the reflectances of the windows WM and WM-1 may increase, and the total thickness of the windows WM and WM-1 may increase, resulting in an excessive increase in the total thickness of the display device DD (see FIG. 2).

The refractive index of the fourth layer FL may be within a range of about 1.3 to about 1.5 at a wavelength of about 550 nm. In the windows WM and WM-1, according to an embodiment, the refractive index of the fourth layer FL at a wavelength of about 550 nm may be within a range of about 1.30 to about 1.35. The refractive index of the fourth layer FL at a wavelength of about 550 nm falls within the above range, and thus the reflectances of the surface of the windows WM and WM-1 may be reduced.

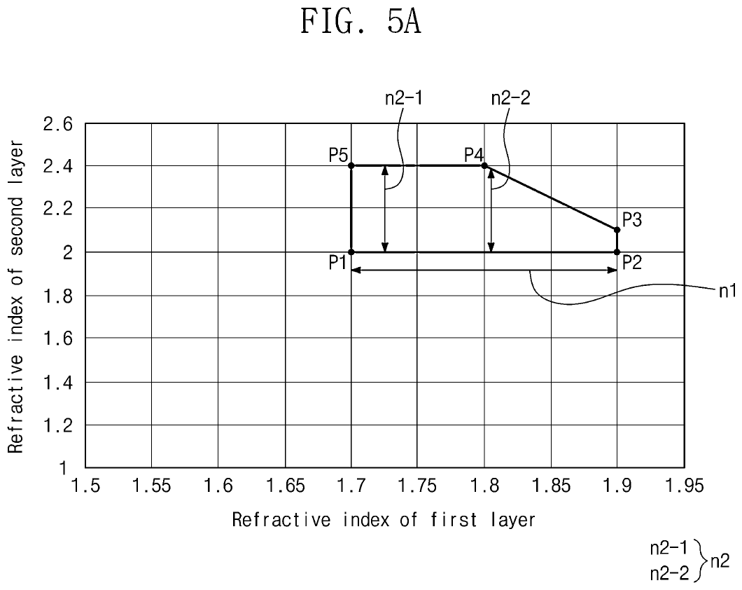

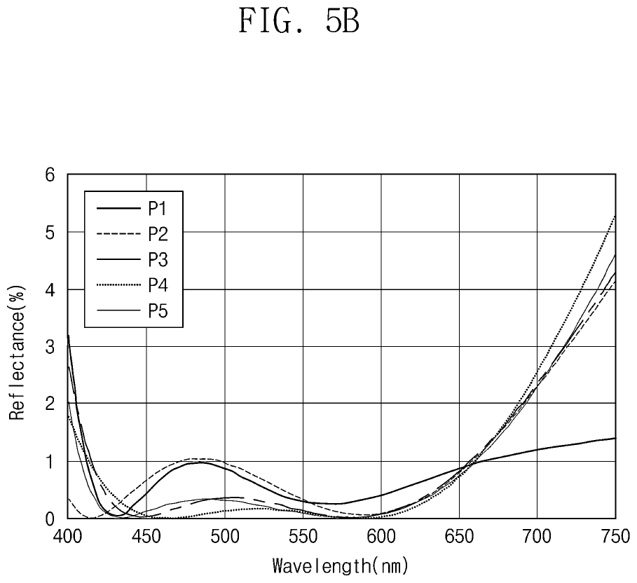

FIG. 5A is a graph showing the refractive indexes of the first layer and the second layer included in a window according to an embodiment of the inventive concept. FIG. 5B is a graph showing the reflectances at some points illustrated in FIG. 5A.

Referring to FIGS. 4A, 4B, 5A and 5B, the first layer RL1 may have a first refractive index n1, and the second layer RL2 may have a second refractive index n2. The first refractive index n1 and the second refractive index n2 may each be a refractive index at a wavelength of about 550 nm.

The first refractive index n1 may be greater than a refractive index of the base layer BL, and less than the second refractive index n2. The first refractive index n1 may be within a range of about 1.7 to about 1.9 at a wavelength of about 550 nm. The windows WM and WM-1, according to an embodiment, may include a first layer RL1 having the first refractive index n1 within a range of about 1.7 to about 1.9, and thus the reflectance of the surface may be reduced.

The second refractive index n2 may be greater than the refractive index of the base layer BL, and the first refractive index n1. The second refractive index n2 may be within a range of about 2.0 to about 2.4 at a wavelength of about 550 nm. The second refractive index n2 may have a first range n2-1 and a second range n2-2 with respect to the range of the first refractive index n1. For example, the second refractive index n2 may have the first range n2-1 when the first refractive index n1 is within a range of about 1.7 to about 1.8, and have the second range n2-2 when the first refractive index n1 is greater than about 1.8 and less than or equal to about 1.9.

In the first refractive index n1 range of about 1.7 to about 1.8, the second refractive index n2 may be in the uniform first range n2-1. The first range n2-1 of the second refractive index n2 may be within a range of about 2.0 to about 2.4. For example, when the first refractive index n1 falls within a range of about 1.7 to about 1.8, the second refractive index n2 may be within a range of about 2.0 to about 2.4.

In the first refractive index n1 range of greater than about 1.8 and less than or equal to about 1.9, the second refractive index n2 may be in the second range n2-2. The second refractive index n2 may be in the second range n2-2 of about 2.0 to about 2.4, and the second range n2-2 may vary depending on the first refractive index n1. For example, when the first refractive index n1 is 1.85, the second range n2-2 of the second refractive index n2 may be within a range of about 2.0 to about 2.25. In addition, when the first refractive index n1 is about 1.9, the second range n2-2 of the second refractive index n2 may be about 2.1 or less. For example, as the first refractive index n1 increases, the second range n2-2 of the second refractive index n2 may exhibit a tendency to decrease.

In an embodiment, when the first refractive index n1 is greater than about 1.8 and less than or equal to about 1.9, the second refractive index n2 may be in the range of Expression 1 below. In Expression 1, n1 means the first refractive index, and n2 means the second refractive index.

$$2. \leq n 2 \leq ( - 3 \times n 1 ) + 7.8 \qquad [ Expression 1 ]$$

For example, the second refractive index n2 in the range of Expression 1 may have a minimum value of about 2.0 and a maximum value of greater than or equal to about 2.1 and less than about 2.4. The windows WM and WM-1, according to an embodiment, may include a second layer RL2 having the second refractive index n2, and thus the reflectance of the surface may be reduced.

A luminous reflectance of the surface of the windows WM and WM-1 may be about 0.5% or less, in the windows WM and WM-1, according to an embodiment. An anti-fingerprint layer FL may be disposed on an uppermost layer, and first to fourth reflectances on an upper surface of the anti-fingerprint layer FL may each be about 1% or less, in the windows WM and WM-1 according to an embodiment. The first reflectance may be a reflectance in a wavelength reign of about 445 nm to about 455 nm, and the second reflectance may be a reflectance in a wavelength reign of about 520 nm to about 530 nm. The third reflectance may be a reflectance in a wavelength reign of about 550 nm to about 560 nm, and the fourth reflectance may be a reflectance in a wavelength reign of about 620 nm to about 630 nm.

In an embodiment, the second reflectance may be higher than the third reflectance. In addition, the second reflectance may be greater than or equal to the first reflectance, and the fourth reflectance may be greater than the third reflectance. In addition, a difference between the second reflectance and the third reflectance may be at least about 0.1, but an embodiment of the inventive concept is not necessarily limited thereto. In an embodiment, the first reflectance may be within a range of about 0.01% to about 0.8%. The second reflectance may be within a range of about 0.15% to about 0.8%, the third reflectance may be within a range of about 0.04% to about 0.3%, and the fourth reflectance may be within a range of about 0.15% to about 0.7%. According to the inventive concept, on the surface, the first to fourth reflectances in the above-described range may exhibit a “W” shaped spectrum. The “W” shaped spectrum within the visible light region, may exhibit relatively higher reflectance in a central wavelength region (e.g., in a wavelength region of approximately about 520 nm to about 560 nm) compared to in a short wavelength region (e.g., in a wavelength region of approximately about 445 nm to about 455 nm) and in a long wavelength region (e.g., in a wavelength region of approximately about 620 nm to about 630 nm). Therefore, blue light and red light may be offset to be white light. Accordingly, colorless windows WM and WM-1 may be achieved within the visible light region.

As used herein, the “reflectance” of the windows WM and WM-1 is defined as a ratio of an amount of light, which is reflected by the surface of the windows WM and WM-1 to the outside, to an amount of light, which is incident toward the inside of the windows WM and WM-1 from the outside. The light reflected by the surfaces of the windows WM and WM-1 to the outside may include specular reflection light, which is incident and then reflected at the same angle, and may include no diffuse reflection light, which is scattered and reflected in various directions. As used herein, the reflectance may be defined as a specular component (SC) reflectance.

In an embodiment, the first refractive index n1 of the first layer RL1 and the second refractive index n2 of the second layer RL2 may be within an area of a polygon, which is formed by connecting the first to fifth points P1 to P5. For example, the first refractive index n1 may be about 1.7, and the second refractive index n2 may be about 2.0 at the first point P1. The first refractive index n1 may be about 1.9, and the second refractive index n2 may be about 2.0 at the second point P2. The first refractive index n1 may be about 1.9, and the second refractive index n2 may be about 2.1 at the third point P3. The first refractive index n1 may be about 1.8, and the second refractive index n2 may be about 2.4 at the fourth point P4. The first refractive index n1 may be about 1.7, and the second refractive index n2 may be about 2.4 at the fifth point P5. The windows WM and WM-1, according to an embodiment, include the first layer to third layer RL1, RL2, and RL3, which have different refractive index ranges from each other, and the refractive index of the first layer RL1 and the refractive index of the second layer RL2 are each within the area of the polygon, which is formed by connecting the first to fifth points P1 to P5. Therefore, the first to fourth reflectances on the surface may be in the above-described range. Accordingly, the colorless windows WM and WM-1 may be achieved, and the reflectances of the surface of the windows WM and WM-1 may be reduced.

FIG. 5B is a graph showing reflectances at the first to fifth points P1 to P5. Referring to FIGS. 5A and 5B, the windows WM and WM-1, according to an embodiment, include a first layer RL1 and a second layer RL2, which have the first refractive index n1 and the second refractive index n2 at the first to fifth points P1 to P5, and thus exhibits a “W” shaped spectrum in the visible light region.

In an embodiment, a ratio of the first refractive index n1 to the second refractive index n2 may be about 1:1.1 to about 1:1.4. When the ratio of the first refractive index n1 to the second refractive index n2 falls within the above-described range, the windows WM and WM-1, according to an embodiment, may exhibit a low reflectance of the surface and have excellent colorless transparency.

The luminous reflectance on the surface of the window WM or WM-1, according to an embodiment, may be about 0.5% or less. The upper surface of the anti-fingerprint layer FL, which is an uppermost layer of the windows WM and WM-1, according to an embodiment, may have the luminous reflectance of about 0.5% or less. The upper surface of the anti-fingerprint layer FL may have the luminous reflectance of about 0.2% to about 0.5%. As used herein, the “luminous reflectance” of the windows WM and WM-1 is defined as a value obtained by multiplying a luminosity factor and a ratio of an amount of light, which is reflected by the surface of the windows WM and WM-1 to the outside, to an amount of light, which is incident toward the inside of the windows WM and WM-1 from the outside.

Referring again to FIGS. 3, 4A, and 4B together, like the display device DD according to an embodiment, when an anti-reflective layer 300 included in the display module DM includes a plurality of color filters 320, display efficiency may be increased compared to a case including a polarization layer, but a reflectance may increase. The windows WM and WM-1, according to an embodiment of the inventive concept, include a base layer BL, and include, on the base layer BL, a first layer RL1 and a second layer RL2, which each have refractive index in a specific range, and a third layer RL3, which has a lower refractive index than the first layer RL1 and the second layer RL2, thereby exhibiting low reflectance properties of the surface. Accordingly, a display device DD including the windows WM and WM-1, according to an embodiment, may have a reflectance of the surface of the overall display device DD maintained to be low.

In an embodiment, the windows WM and WM-1 including the first to third layers RL1, RL2 and RL3 may have a saturation (C*) of about 3 or less by Expression 2 below. In Expression 2, C* means a saturation, and a* and b* each mean a CIE color coordinate, which is a color space developed by the International Commission on Illumination (CIE). The windows WM and WM-1 according to an embodiment may exhibit a saturation of about 3 or less, and thus exhibit a “W” shaped spectrum, thereby exhibiting excellent colorless transparency.

$$C *= \sqrt{{{( a \text{*)}}^{2} + ( b \text{*)}}^{2}} \qquad [ Expression 2 ]$$

In an embodiment, when the first layer to third layers RL1, RL2, and RL3 are included, and the first layer RL1 and the second layer RL2 are controlled to have specific refractive indexes, the display device may have reduced external light reflection, and the colorless transparency of windows WM and WM-1 may be increased, thereby making it possible to exhibit excellent display quality. In order to exhibit low-reflection properties on the surface of the windows WM and WM-1 and excellent colorless transparency, the thicknesses of the first layer to the third layer RL1, RL2, and RL3 may be adjusted according to the refractive indexes of the first layer RL1 and the second layer RL2.

In Table 1 below, optical properties of a window WM, as illustrated in FIG. 5A, which includes the base layer BL, the first layer to the third layer RL1, RL2, and RL3, and the anti-fingerprint layer FL were evaluated, and the results were listed. In Table 1, reflectance, and a* and b* were measured using a spectrophotometer (CM-3800A instrument made by Konika Minolta, Inc.). The reflectance is an SC reflectance obtained by measuring both a specular component included (SCI) reflectance and a specular component excluded (SCE) reflectance in a reflection mode and then calculating as “the SCI reflectance-the SCE reflectance”. The refractive index was measured using an ellipsometer, wherein the M-2000 instrument made by J. A. Woolam Co., was used. In addition, the refractive index was measured at a wavelength of about 550 nm by forming the first layer RL1 and the second layer RL2 on a glass as a single film respectively.

TABLE 1

| | Thickness (nm) | | | | | | | | | First layer | |
|---|---|---|---|---|---|---|---|---|---|---|---|
| | Anti- | | | | | | | | Second layer | refractive | |
| | fingerprint | Third | Second | First | Optical properties | | | | refractive | index | |
| | layer | layer | layer | layer | Reflectance(%) | a* | b* | C* | index(n2) | (n1) | n2/n1 |
| Example 1 | 25 | 74 | 129 | 86 | 0.39 | 0.36 | 0.18 | 0.4 | 2.04 | 1.7 | 1.2 |
| Example 2 | 25 | 64 | 104 | 67 | 0.2 | −0.12 | 0.27 | 0.3 | 2.21 | 1.7 | 1.3 |
| Example 3 | 25 | 68 | 100 | 71 | 0.14 | −0.38 | 0.06 | 0.38 | 2.38 | 1.7 | 1.4 |
| Example 4 | 25 | 74 | 128 | 91 | 0.28 | 0.26 | −1.43 | 1.45 | 2.1 | 1.75 | 1.2 |
| Example 5 | 25 | 69 | 103 | 65 | 0.13 | 0.14 | −0.54 | 0.56 | 2.275 | 1.75 | 1.3 |
| Example 6 | 25 | 69 | 100 | 64 | 0.09 | −0.4 | 0.06 | 0.4 | 2.38 | 1.75 | 1.36 |
| Example 7 | 25 | 69 | 102 | 60 | 0.23 | −0.06 | −0.43 | 0.43 | 2.38 | 1.8 | 1.32 |
| Example 8 | 25 | 66 | 90 | 52 | 0.16 | −0.34 | −0.18 | 0.38 | 2.16 | 1.8 | 1.2 |
| Example 9 | 25 | 66 | 88 | 52 | 0.16 | −0.38 | 0.2 | 0.43 | 2.22 | 1.85 | 1.2 |
| Example 10 | 25 | 70 | 51 | 70 | 0.21 | −0.48 | 0.06 | 0.48 | 2.035 | 1.85 | 1.1 |
| Example 11 | 25 | 68 | 57 | 63 | 0.18 | 0.17 | 0.1 | 0.2 | 2.09 | 1.9 | 1.1 |
| Comparative | 25 | 64 | 114 | 76 | 0.48 | −5.41 | −6.18 | 8.21 | 2.07 | 1.6 | 1.3 |
| Example 1 | | | | | | | | | | | |
| Comparative | 25 | 62 | 109 | 61 | 1.01 | 1.52 | −2.25 | 2.72 | 1.76 | 1.6 | 1.1 |
| Example 2 | | | | | | | | | | | |
| Comparative | 25 | 62 | 99 | 57 | 0.8 | 0.19 | −0.36 | 0.41 | 1.815 | 1.65 | 1.1 |
| Example 3 | | | | | | | | | | | |
| Comparative | 25 | 59 | 109 | 64 | 0.55 | 0.5 | −0.73 | 0.88 | 1.98 | 1.65 | 1.2 |
| Example 4 | | | | | | | | | | | |
| Comparative | 25 | 62 | 110 | 70 | 0.35 | −2.16 | −2.54 | 3.33 | 2.145 | 1.65 | 1.3 |
| Example 5 | | | | | | | | | | | |
| Comparative | 25 | 76 | 151 | 92 | 0.65 | −0.27 | 0.02 | 0.27 | 1.87 | 1.7 | 1.1 |
| Example 6 | | | | | | | | | | | |
| Comparative | 25 | 77 | 144 | 93 | 0.53 | −1.96 | −3.16 | 3.72 | 1.925 | 1.75 | 1.1 |
| Example 7 | | | | | | | | | | | |
| Comparative | 25 | 67 | 99 | 59 | 0.38 | 0.21 | 0.46 | 0.51 | 2.38 | 1.85 | 1.286 |
| Example 8 | | | | | | | | | | | |
| Comparative | 25 | 64 | 84 | 56 | 0.35 | −0.34 | 0.04 | 0.34 | 2.236 | 1.9 | 1.177 |
| Example 9 | | | | | | | | | | | |
| Comparative | 25 | 63 | 88 | 54 | 0.35 | 0.33 | −0.25 | 0.41 | 2.38 | 1.9 | 1.253 |
| Example 10 | | | | | | | | | | | |

These 125 samples were manufactured by combining the thicknesses of the first to third layers RL1, RL2, and RL3 in the windows according to Examples and Comparative Examples in Table 1, each within a range of +2 nm. The reflectance and C* were measured for each sample and average values were listed in Table 2 below.

For example, Comparative Example 1 in Table 2 shows reflectances and C* values of 125 windows that are made up of the first layer RL1 having thicknesses of about 74 nm, about 75 nm, about 76 nm, about 77 nm, and about 78 nm, the second layer RL2 having thicknesses of about 112 nm, about 113 nm, about 114 nm, about 115 nm, and about 116 nm, and the third layer RL3 having thicknesses of about 62 nm, about 63 nm, about 64 nm, about 65 nm, and about 66 nm.

TABLE 2

| | |
|---|---|
| Reflectance | C* |

| | | Standard | | Standard |
|---|---|---|---|---|
| | Average | deviation | Average | deviation |
| Example 1 | 0.42% | 0.04% | 2.76 | 1.32 |
| Example 2 | 0.24% | 0.09% | 2.86 | 1.55 |
| Example 3 | 0.20% | 0.06% | 2.47 | 1.4 |
| Example 4 | 0.31% | 0.04% | 3.97 | 1.54 |
| Example 5 | 0.17% | 0.08% | 3.34 | 2.17 |
| Example 6 | 0.15% | 0.07% | 2.15 | 1.21 |
| Example 7 | 0.27% | 0.16% | 3.93 | 2.19 |
| Example 8 | 0.21% | 0.05% | 3 | 1.4 |
| Example 9 | 0.21% | 0.08% | 2.96 | 1.64 |
| Example 10 | 0.25% | 0.05% | 3.08 | 1.47 |
| Example 11 | 0.23% | 0.04% | 2.97 | 1.81 |
| Comparative | 0.51% | 0.11% | 9.62 | 1.11 |
| Example 1 | | | | |
| Comparative | 1.03% | 0.08% | 3.22 | 1.5 |
| Example 2 | | | | |
| Comparative | 0.82% | 0.09% | 2.78 | 1.44 |
| Example 3 | | | | |
| Comparative | 0.57% | 0.13% | 2.81 | 1.38 |
| Example 4 | | | | |
| Comparative | 0.39% | 0.12% | 4.95 | 1.28 |
| Example 5 | | | | |
| Comparative | 0.67% | 0.03% | 3.59 | 1.62 |
| Example 6 | | | | |
| Comparative | 0.55% | 0.07% | 5.99 | 2.6 |
| Example 7 | | | | |
| Comparative | 0.43% | 0.22% | 5.54 | 3.06 |
| Example 8 | | | | |
| Comparative | 0.39% | 0.20% | 3.64 | 2.42 |
| Example 9 | | | | |
| Comparative | 0.41% | 0.23% | 4.23 | 2.46 |
| Example 10 | | | | |

Referring to Tables 1 and 2, the windows, according to Examples, have reflectances of about 0.5% or less and C* of about 3 or less. For example, it can be confirmed that, in the windows according to Examples 1 to 11, when a first refractive index n1 is within a range of about 1.7 to about 1.8, and when the first refractive index n1 is greater than about 1.8 and less than or equal to about 1.9 while a second refractive index n2 is about 2.0 to about 2.4, the above-described range of Expression 1 is satisfied, and thus the windows according to Examples 1 to 11 exhibit reduced reflectance and C* value that may achieve colorless transparency. In addition, the windows according to Examples have a standard deviation of the reflectance of less than about 0.2%, and thus a process dispersion is small. Therefore, all of them may be expected to exhibit reduced reflectance.

Compared to this, the windows according to Comparative Examples do not have first refractive index n1 and/or second refractive index n2 according to the inventive concept, thereby not exhibiting results of the reduced reflectance and/or C*. The windows according to Comparative Examples 1 and 5, didn't exhibit a result of the reduced C* than Examples, and the windows according to Comparative Examples 2 to 4, and 6, didn't exhibit a result of the reduced reflectance. In addition, Comparative Example 7 didn't exhibited a result in that both the reflectance and C* were reduced. In the case of Comparative Examples 8 to 10, the standard deviation of the reflectance is at least about 0.2%, and thus the reflectance may deviate from 0.5% due to a process dispersion.

The evaluation results of optical properties of the window according to Example A were listed, in Table 3 below. The evaluation results of scratch-resistance, chemical-resistance, and abrasion-resistance of the window of Example A listed in Table 3 were listed, in Table 4.

In Tables 3 and 4, the window according to Example A, as illustrated in FIG. 4A, has a structure in which the first layer to a third layer RL1, RL2, and RL3 and the anti-fingerprint layer FL are sequentially stacked on the base layer BL. In the window according to Example A, the base layer BL was formed from a glass substrate, the first layer RL1 was formed of a solid solution, in which tantalum pentoxide (Ta₂O₅) and aluminum oxide (Al₂O₃) were mixed, the second layer RL2 was formed of a solid solution, in which tantalum pentoxide (Ta₂O₅) and zirconium oxide (ZrO₂) were mixed, and the third layer RL3 was formed of silicon dioxide (SiO₂). The anti-fingerprint layer FL was formed of perfluoropolyether (PFPE). Thicknesses of the first layer to the third layer RL1, RL2, and RL3 and the anti-fingerprint layer FL are the same as listed in Table 3 below. In Table 3, reflectance, a* and b* were measured in the same manner as Examples in Table 1.

TABLE 3
Example A

| | | |
|---|---|---|
| Thickness(nm) | Anti-fingerprint layer | 25 |
| | Third layer | 79 |
| | Second layer | 107 |
| | First layer | 72 |

| | |
|---|---|
| Reflectance (%) | 0.35 |
| a* | −0.23 |
| b* | −1.57 |

In Table 4, a scratch resistance was evaluated by measuring a water contact angle with respect to the window surface after performing a scratch resistance test using an eraser. In the scratch resistance evaluation, the window according to Example A was cut to about 7 cm×about 8 cm and fixed to a scratch resistance measuring instrument (scratch tester made by Daesung Precision Co.) jig, and an eraser with a diameter of about 6 mm (Rubber stick, made by Minoan Co.) was mounted and fixed to the TIP. A movement distance to 15 mm, a movement speed to 50 rpm, and a load to 1.0 kg were set, the eraser was rubbed back and forth on the window surface 10,000 times, and then the contact angle of the window surface was measured.

In Table 4, an abrasion resistance evaluation was performed by abrading with a steel-wool under a load of about 1 Kgf for 5,000 times and then measuring the water contact angle of the window surface. Chemical resistance evaluation was performed by applying chemical onto the window surface and scratching with a rubber, and then measuring the water contact angle of the window surface. For example, the window according to Example A was cut to about 7 cm×about 8 cm and fixed to a scratch resistance measurement instrument (scratch tester made by Daesung Precision Co.) jig, and an eraser with a diameter of about 6 mm (Rubber stick, made by Minoan Co.) was mounted and fixed to the TIP. Pure ethanol was applied on the surface of a window for a test, and in the presence of ethanol, the movement distance to 15 mm, the movement speed to 50 rpm, and the load to 1.0 kg were set. The eraser was rubbed back and forth on the surface of the window for a test 10,000 times, and then the surface was cleaned several times to measure the water contact angle of the abraded surface.

TABLE 4

| | |
|---|---|
| Initial contact angle (°) | 115 |
| Scratch resistance: after scratching | 110 or more |
| of 10K times with an eraser (°) | |
| Abrasion resistance: after abrading | 100 or more |
| 5K times with steel wool (°) | |
| Chemical resistance: after | 100 or more |
| scratching 10K times (°) | |

Referring to Table 3, the window according to Example A exhibited a* and b*, of which a reflectance was about 0.5% or less, and C* was about 3. From this result, it can be confirmed that the window according to Example A exhibits a low reflectance and excellent colorless transparency.

In addition, referring to Table 4, the water contact angle of the window according to Example A has been maintained at about 110° or more even after the scratch resistance evaluation, and the water contact angle has been maintained at about 100° or more even after the abrasion resistance evaluation and the chemical resistance evaluation. Therefore, it can be confirmed that scratch resistance, abrasion resistance and chemical resistance are excellent.

The window, according to an embodiment, includes a plurality of layers exhibiting a specific refractive index to exhibit excellent optical properties with reduced reflectance, and mechanical strength such as a scratch resistance property, a chemical resistance property, and an abrasion resistance property, may be increased. Accordingly, a display device including a window, according to an embodiment, may have excellent display quality and increased resistance and reliability.

Hitherto, the inventive concept has been described with reference to a preferred embodiment of the inventive concept, but it is understood by those skilled in the art or having ordinary knowledge of the art that various changes and modifications can be made without departing from the spirit and scope of the inventive concept.

Accordingly, it is understood that the technical scope of the inventive concept should not necessarily be limited to the contents set forth in the detailed description of the specification.

What is claimed is:

1. A window, comprising:
a base layer;
a first layer disposed on the base layer, and having a first refractive index within a range of about 1.7 to about 1.9;
a second layer disposed on the first layer, and having a second refractive index that is larger than the first refractive index; and
a third layer disposed on the second layer, and having a third refractive index that is less than each of the first refractive index and the second refractive index,
wherein when the first refractive index is within a range of about 1.7 to about 1.8, the second refractive index is in a range of about 2.0 to about 2.4, and when the first refractive index is greater than about 1.8 and equal to or less than about 1.9, the second refractive index is in a range of: 2.0≤n2≤ (−3×n1)+7.8
where,
n1 is the first refractive index, and
n2 is the second refractive index.

2. The window of claim 1, further comprising an anti-fingerprint layer disposed on the third layer.

3. The window of claim 2, wherein the second layer is disposed directly on the first layer, the third layer is disposed directly on the second layer, and the anti-fingerprint layer is disposed directly on the third layer.

4. The window of claim 2, further comprising an adhesive layer disposed between the first layer and the second layer, and/or between the second layer and the third layer.

5. The window of claim 2, wherein the first layer has a thickness within a range of about 50 nm to about 95 nm,
wherein the second layer has a thickness within a range of about 50 nm to about 150 nm,
wherein the third layer has a thickness within a range of about 50 nm to about 80 nm, and
wherein the anti-fingerprint layer has a thickness within a range of about 20 nm to about 45 nm.

6. The window of claim 2, wherein first to fourth reflectances on an upper surface of the anti-fingerprint layer are each about 1% or less, the second reflectance is higher than the third reflectance,
wherein the first reflectance is a specular component (SC) reflectance in a wavelength range of about 445 nm to about 455 nm,
wherein the second reflectance is an SC reflectance in a wavelength range of about 520 nm to about 530 nm,
wherein the third reflectance is an SC reflectance in a wavelength range of about 550 nm to about 560 nm, and
wherein the fourth reflectance is an SC reflectance in a wavelength range of about 620 nm to about 630 nm.

7. The window of claim 6, wherein the second reflectance is at least equal to the first reflectance,
wherein the fourth reflectance is greater than the third reflectance, and
wherein a difference between the second reflectance and the third reflectance is at least 0.1.

8. The window of claim 7, comprising:
a first point in which the first refractive index is about 1.7, and the second refractive index is about 2.0;
a second point in which the first refractive index is about 1.9, and the second refractive index is about 2.0;
a third point in which the first refractive index is about 1.9, and the second refractive index is about 2.1;
a fourth point in which the first refractive index is about 1.8, and the second refractive index is about 2.4; and
a fifth point in which the first refractive index is about 1.7, and the second refractive index is about 2.4,
wherein, within an area of a polygon, which is formed by connecting the first to fifth points,
the first reflectance is about 0.01% to about 0.8%,
the second reflectance is about 0.15% to about 0.8%,
the third reflectance is about 0.04% to about 0.3%, and
the fourth reflectance is about 0.15% to about 0.7%.

9. The window of claim 1, wherein the third layer has a refractive index within a range of about 1.48 to about 1.5.

10. The window of claim 1, wherein the third layer comprises silicon dioxide (SiO₂).

11. The window of claim 1, wherein a ratio of the first refractive index to the second refractive index is about 1:1.1 to about 1:1.4.

12. The window of claim 1, wherein the first layer comprises tantalum pentoxide (Ta₂O₅) and aluminum oxide (Al₂O₃).

13. The window of claim 1, wherein the second layer comprises tantalum pentoxide (Ta₂O₅) and zirconium oxide (ZrO₂).

14. The window of claim 1, wherein a luminous reflectance on an uppermost surface is about 0.5% or less.

15. The window of claim 1, wherein a saturation of C* is about 3 or less in the equation:
$$C *= \sqrt{{{( a \text{*)}}^{2} + ( b \text{*)}}^{2}}$$
where, a* and b* are each CIE color coordinates.

16. A window, comprising:
a base layer;
a first layer disposed on the base layer, and having a first refractive index within a range of about 1.7 to about 1.9;
a second layer disposed on the first layer, and having a second refractive index that is higher than the first refractive index; and
a third layer disposed on the second layer, and has a third refractive index that is lower than the first refractive index,
wherein on an uppermost surface, the window has first to fourth reflectances, each of which is about 1% or less,
wherein the first reflectance is about 0.01% to about 0.8% in a wavelength range of about 445 nm to about 455 nm,
wherein the second reflectance is about 0.15% to about 0.8% in a wavelength range of about 520 nm to about 530 nm,
wherein the third reflectance is about 0.04% to about 0.3% in a wavelength range of about 550 nm to about 560 nm, and
wherein the fourth reflectance is about 0.15% to about 0.7% in a wavelength range of about 620 nm to about 630 nm.

17. The window of claim 16, wherein when the first refractive index is about 1.7 to about 1.8, the second refractive index is in a range of about 2.0 to about 2.4, and when the first refractive index is greater than about 1.8 and equal to or less than about 1.9, the second refractive index is in a range of:
$$2. \leq n 2 \leq ( - 3 \times n 1 ) + 7.8$$
where,
n1 is the first refractive index, and
n2 is the second refractive index.

18. A display device, comprising:
a display module including a base substrate, a circuit layer disposed on the base substrate, a light-emitting element layer disposed on the circuit layer, a sensor layer disposed on the light-emitting element layer, and a light control layer disposed on the sensor layer; and
a window disposed on the display module,
wherein the window includes:
a base layer;
a first layer disposed on the base layer, and having a first refractive index within a range of about 1.7 to about 1.9;
a second layer disposed on the first layer, and having a second refractive index that is greater than the first refractive index, and
a third layer disposed on the second layer, and having a third refractive index that is less than each of the first refractive index and the second refractive index, and
when the first refractive index is within a range of about 1.7 to about 1.8, the second refractive index is in a range of about 2.0 to about 2.4, and when the first refractive index is greater than 1.8 and at most 1.9, the second refractive index is in a range of:
$$2. \leq n 2 \leq ( - 3 \times n 1 ) + 7.8$$
where,
n1 is the first refractive index, and
n2 is the second refractive index.

19. The display device of claim 18, wherein a ratio of the first refractive index to the second refractive index is about 1:1.1 to about 1:1.4.

20. The display device of claim 18,
wherein the first layer has a thickness within a range of about 50 nm to about 95 nm,
wherein the second layer has a thickness within a range of about 50 nm to about 150 nm, and
wherein the third layer has a thickness within a range of about 50 nm to about 80 nm.
